(19) United States
(12) Patent Application Publication
(10) Pub. No.: US 2011/0147753 A1
(43) Pub. Date: Jun. 23, 2011

(54) DISPLAY DEVICE, COPPER ALLOY FILM FOR USE THEREIN, AND COPPER ALLOY SPUTTERING TARGET

(75) Inventors: Takashi Onishi, Hyogo (JP); Aya Miki, Hyogo (JP); Hiroshi Goto, Hyogo (JP); Masao Mizuno, Hyogo (JP); Hirotaka Ito, Hyogo (JP); Katsufumi Tomihisa, Hyogo (JP)

(73) Assignee: Kabushiki Kaisha Kobe Seiko Sho (Kobe Steel, Ltd.), Kobe-Shi (JP)

(21) Appl. No.: 13/056,444

(22) PCT Filed: Aug. 14, 2009
(86) PCT No.: PCT/JP09/64338

§ 371 Date: Jan. 28, 2011

(30) Foreign Application Priority Data
Aug. 14, 2008 (JP) 2008-208960

(51) Int. Cl. H01L 29/04; B32B 17/06

(52) U.S. Cl. 257/59; 257/72; 428/433; 428/336; 257/E29.003

(57) ABSTRACT

Disclosed is a Cu alloy film for a display device that has high adhesion to a glass substrate while maintaining a low electric resistance characteristic of Cu-based materials. The Cu alloy film is wiring in direct contact with a glass substrate on a board and contains 0.1 to 10.0 atomic % in total of one or more elements selected from the group consisting of Ti, Al, and Mg. Also disclosed is a display device comprising a thin-film transistor that comprises the Cu alloy film. In a preferred embodiment of the display device, the thin-film transistor has a bottom gate-type structure, and a gate electrode and scanning lines in the thin-film transistor comprise the Cu alloy film and are in direct contact with the glass substrate.

### TECHNICAL FIELD

The present invention relates to a display device and a Cu alloy film for use in the display device. Specifically, the present invention relates to a Cu alloy film constituting an interconnection to be in direct contact with a glass substrate of a thin film transistor (hereinafter also referred to as a “TFT”) of such a display device; to a flat panel display (display device) such as a liquid crystal display or organic electroluminescent (EL) display, which includes the Cu alloy film used in the thin film transistor; and to a sputtering target for the deposition of the Cu alloy film. Of such display devices, the following description is made by taking liquid crystal displays as examples. It should be noted, however, that these examples are never intended to limit the scope of the present invention.

### BACKGROUND ART

Typically, liquid crystal displays are used in a wide variety of applications ranging from small-sized mobile phones to wide-screen television sets of more than 100 inches in size. The liquid crystal displays are classified as simple matrix liquid crystal displays and active matrix liquid crystal displays by the addressing method of pixels. Among them, active matrix liquid crystal displays including TFTs as switching devices have high image quality, allow display of high-speed animations, and are thereby in mainstream of liquid crystal displays.

FIG. 1 illustrates a configuration of a representative liquid crystal display adopted to active matrix liquid crystal displays. The configuration and operating principle of this liquid crystal display will be described with reference to FIG. 1.

The liquid crystal display 100 has a structure including two-dimensionally arrayed pixel units, in which each of the pixel units includes a TFT array substrate 1; a counter substrate (opposite substrate) 2 facing the TFT array substrate 1; and a liquid crystal layer 3 being arranged between the TFT array substrate 1 and the counter substrate 2 and functioning as a light modulating layer.

The TFT array substrate 1 includes an insulative glass substrate 1a supporting thereon TFTs 4, pixel electrodes (transparent conductive film) 5, and an interconnection unit 6 including scanning lines and signal lines.

The counter substrate 2 includes a glass plate; a common electrode 7 formed over the entire surface of the glass plate; color filters 8 facing the pixel electrodes (transparent conductive film) 5 of the TFT array substrate 1; and a light shielding film 9 facing the TFTs 4 and the interconnection unit 6 on the TFT array substrate 1. The counter substrate 2 further includes an alignment layer 11 to orient in a desired direction liquid crystal molecules contained in the liquid crystal layer.

TFT array substrate 1 and the counter substrate 2 have polarizers 10a and 10b, respectively, on their outer sides (opposite to the liquid crystal layer).

In each pixel of the liquid crystal display 100, an electric field between the counter substrate 2 and the pixel electrode (transparent conductive film) 5 is controlled by the TFT 4, the controlled electric field changes the alignment of liquid crystal molecules in the liquid crystal layer 3 and thereby modulates (shields or transmits) light passing through the liquid crystal layer 3. This controls the quantity of light passing through the counter substrate 2 to thereby display as an image.

A backlight 22 is provided in a lower section of the liquid crystal display 100, and light emitted from the backlight 22 passes from the bottom to the top in FIG. 1.

The TFT array substrate 1 is driven by a drive circuit 13 and a control circuit 14 both connected thereto through a TAB (tape automated bonding) tape 12.

Shown also in FIG. 1 are a spacer 15, a sealant 16, a protective film 17, a diffuser panel 18, a prism sheet 19, a light guide panel 20, a reflector plate 21, a holding frame 23, and a printed circuit board 24.

FIG. 2 is an enlarged view of the essential part A shown in FIG. 1 and includes a scanning line (gate interconnection) 25 arranged on the glass substrate 1a, and part of the scanning line 25 functions as a gate electrode 26 to control on and off of the TFT. A gate insulating film (SiN) 27 is arranged so as to cover the gate electrode 26. A signal line (source-drain interconnection) 34 is arranged so as to intersect the scanning line 25 with the interposition of the gate insulating film 27, and part of the signal line 34 functions as a source electrode 28 of the TFT. On the gate insulating film 27 are sequentially arranged an amorphous silicon channel layer (active semiconductor layer), the signal line (source-drain interconnection) 34, and a passivation film (protective film, silicon nitride film) 30. A device of this type is generally called a “bottom-gate” device.

In a pixel region above the gate insulating film 27 is arranged the pixel electrode (transparent conductive film) 5 formed typically from an indium tin oxide (ITO) film containing indium oxide (In₂O₃) and about 10 percent by mass of tin oxide (SnO), or an indium zinc oxide (IZO) film containing indium oxide (In₂O₃) and zinc oxide. The drain electrode 29 in FIG. 2 is directly contacted with and electrically connected to the pixel electrode (transparent conductive film) 5.

The TFT 4 is turned on as a gate voltage is applied via the scanning line of the gate electrode 26 in the TFT array substrate. A driving voltage, which has been previously applied to the signal line, is applied from the source electrode 28 through the drain electrode 29 to the pixel electrode (transparent conductive film) 5. As the pixel electrode (transparent conductive film) 5 is supplied with the driving voltage at a certain level, a sufficient electric potential is generated between the transparent pixel electrode 5 and the counter electrode 2 to orient the liquid crystal molecules in the liquid crystal layer 3, resulting in light modulation.

A reflecting electrode (not shown) may be provided above the TFT for higher brightness (luminance). An end of the drain electrode 29 is in electric contact with the pixel electrode (transparent conductive film) 5, and, in addition, the pixel electrode (transparent conductive film) 5 may be in contact with the reflecting electrode.

A certain voltage is applied between the source electrode 28 and the drain electrode 29 of the TFT shown in FIG. 2. The liquid crystal display is also possible to display animations (moving images) by controlling on and off of the voltage of the gate electrode 26, whereby controlling a current passing from the source electrode 28 through the channel layer to the drain electrode 29, controlling the electric field of the liquid crystal layer 3 through the pixel electrodes 5, and thereby modulating quantities of light passing through the respective pixels.

The source-drain interconnection 34, the scanning line 25, and the gate electrode 26 have been customarily formed from thin films of Al-based alloys (such as Al—Nd alloys), because typically of easy working of these alloys.

However, there are recently increasing demands to provide interconnection materials having lower electric resistances, because the interconnections should essentially have further lower electric resistances under such circumstances that liquid crystal displays are designed to have larger sizes and to operate at a frequency of not 60 kHz but 120 kHz. Accordingly, Cu materials receive attentions to be adopted mainly to large-sized panels for television sets, because they have lower electric resistivities and have more excellent hillock resistance than those of Al materials such as pure Al and Al alloys. In this connection, as metals (bulk materials), the pure Al has an electric resistivity at room temperature of 2.7×10⁻⁶ Ω·cm, whereas the pure Cu has an electric resistivity at room temperature of 1.8×10⁻⁶ Ω·cm.

For establishing direct contact between a transparent conductive film and a Cu alloy film, the present applicants have also proposed, as the Cu alloy film, a Cu alloy film containing (i) Zn and/or Mg, or containing (ii) Ni and/or Mn, or further containing (iii) Fe and/or Co as alloy elements (Patent Literature (PTL) 1).

However, such Cu-based materials, when adopted to interconnections, have poor adhesion to a glass substrate and/or insulating film as compared to the Al-based materials. Particularly when arranged on the glass substrate, the known Cu-based materials have the following problems. Specifically, the glass substrate of a liquid crystal display generally uses a glass containing components such as SiO₂, Al₂O₃, BaO, and B₂O₃ as the main component. An electrode/interconnection composed of a Cu-based material (hereinafter referred to as a “Cu-based electrode/interconnection” or “Cu-based interconnection”) has poor adhesion to the glass substrate and often suffers from peeling off from the glass substrate. The present applicants have conceived that the technique disclosed in PTL 1 does not sufficiently discuss about adhesion between the Cu alloy film and the glass substrate or insulating film, and that further investigations are necessary for allowing a Cu alloy film to have higher adhesion typically to the glass substrate.

For the above reason, liquid crystal displays using the customary Cu-based electrode/interconnection structurally include an underlayer (pure Mo layer, Mo—Ti alloy layer, or another Mo-containing underlayer) arranged between the glass substrate and the Cu-based electrode/interconnection. Typically, an exemplary liquid crystal display employs an interconnection with a bilayer structure including a Mo-containing underlayer and, arranged thereon, a thin film of pure Cu.

For example, PTL 2 to 4 disclose techniques of arranging a layer of a high-melting-point metal such as molybdenum (Mo) or chromium (Cr) between a Cu-based interconnection and a glass substrate, in order to improve the adhesion between the Cu-based interconnection and the glass substrate and to suppress lifting (pop-off) and rupture of the Cu-based interconnection during patterning.

These bilayer structure interconnections, however, require complicated processes and suffer from increased process cost. In addition, they also suffer from high interconnection resistance as the whole bilayer structure (effective interconnection resistance), because they include the Mo-containing underlayer having a high electric resistance as the interconnection underlayer. Specifically, as Cr and Mo have electric resistivities higher than that of Cu (Cr has an electric resistivity of 12.9×10⁻⁶ Ω·cm; and Mo has an electric resistivity of 10.0×10⁻⁶Ω·cm), the bilayer interconnections including the Cu-based interconnection and the high-melting-point metal layer suffer from problems of signal delay and power loss caused by high interconnection electric resistances. In addition, the bilayer interconnections may suffer from corrosion at the interface between Cu and the high-melting-point metal during wet etching using a chemical bath (liquid chemical), because metals of different types, i.e., Cu and the high-melting-point metal (such as Mo) are laminated. The lamination of the thin films of different materials impedes taper control through wet etching in pattering to form the interconnection. Specifically, typically when the underlayer in the bilayer structure is etched at a rate higher than that of the upper layer, the underlayer is necked to generate an undercut, and this can impede the formation of the interconnection having a desired profile (cross section) (e.g., a profile with a taper angle of about 45 degrees to about 60 degrees).

PTL 5 discloses a technique of arranging, as adhesion layers, nickel or a nickel alloy and a polymeric resin film between a Cu-based interconnection and a glass substrate. According to this technique, however, the resin film may deteriorate to have insufficient adhesion during a high-temperature annealing process in the production of a display device (such as a liquid crystal display panel).

### CITATION LIST

### Patent Literature

PTL 1: Japanese Unexamined Patent Application Publication (JP-A) No. 2007-17926
PTL 2: Japanese Unexamined Patent Application Publication (JP-A) No. H07 (1995)-66423
PTL 3: Japanese Unexamined Patent Application Publication (JP-A) No. H08 (1996)-8498
PTL 4: Japanese Unexamined Patent Application Publication (JP-A) No. H08 (1996)-138461
PTL 5: Japanese Unexamined Patent Application Publication (JP-A) No. H10 (1998)-186389

### SUMMARY OF INVENTION

### Technical Problem

Under these circumstances, an object of the present invention is to provide a Cu alloy film having high adhesion to a glass substrate (“adhesion to a glass substrate” is hereinafter also simply referred to as “adhesion”; and “glass substrate” is hereinafter also simply referred to as “substrate”) while maintaining a low electric resistance, a feature of Cu-based materials; and to provide a Cu alloy film further having satisfactory etching properties in addition to the high adhesion. Another object of the present invention is to provide a flat panel display (display device), typified by a liquid crystal display, using the Cu alloy film in TFTs (especially preferably in gate electrodes and scanning lines of the TFTs) without forming the Mo-containing underlayer. Yet another object of the present invention is to provide a sputtering target for the deposition of the Cu alloy film having the above-mentioned excellent performance.

### Solution to Problem

Summary of the present invention will be illustrated below.

(1) A Cu alloy film (Cu alloy interconnection thin film) for a display device, the Cu alloy film working as an interconnection to be arranged on and in direct contact with a glass substrate, in which the Cu alloy film contains one or more elements selected from the group consisting of Ti, Al, and Mg in a total content of 0.1 to 10.0 atomic percent.

(2) A Cu alloy film (Cu alloy interconnection thin film) for a display device, the Cu alloy film working as an interconnection to be arranged on and in direct contact with a glass substrate, in which the Cu alloy film contains one or more elements selected from the group consisting of Ti, Al, and Mg in a total content of 0.1 to 5.0 atomic percent.

(3) A Cu alloy film (Cu alloy interconnection thin film) for a display device, the Cu alloy film working as an interconnection to be arranged on and in direct contact with a glass substrate, in which the Cu alloy film contains one or more elements selected from the group consisting of Ti, Al, and Mg in a total content of 0.2 to 10.0 atomic percent.

(4) The Cu alloy film for a display device according to Item (3), in which the Cu alloy film has a multilayer structure including an underlayer containing oxygen; and an upper layer being substantially free from oxygen, and the underlayer is in contact with the substrate.

(5) A Cu alloy film (Cu alloy interconnection thin film) for a display device, the Cu alloy film working as an interconnection to be arranged on and in direct contact with a glass substrate,

in which the Cu alloy film has a multilayer structure including:
an underlayer including oxygen and a Cu alloy containing one or more elements selected from the group consisting of Ti, Al, and Mg in a total content of 0.2 to 10.0 atomic percent; and
an upper layer being substantially free from oxygen and containing pure Cu or a Cu alloy, the Cu alloy containing Cu as a main component and having an electric resistivity lower than that of the underlayer, and

the underlayer is in contact with the substrate.

The Cu alloy film for a display device is preferably:

a Cu alloy film for a display device, the Cu alloy film working as an interconnection to be arranged on and in direct contact with a glass substrate,

in which the Cu alloy film has a multilayer structure including:
an underlayer being composed of oxygen and a Cu alloy containing one or more elements selected from the group consisting of Ti, Al, and Mg in a total content of 0.2 to 10.0 atomic percent; and
an upper layer being substantially free from oxygen and being composed of pure Cu or a Cu alloy, the Cu alloy containing Cu as a main component and having an electric resistivity lower than that of the underlayer, and

the underlayer is in contact with the substrate.

(6) The Cu alloy film for a display device according to Item (4) or (5), wherein the underlayer has been formed through sputtering with a sputtering gas having an oxygen content of 1 percent by volume or more and less than 20 percent by volume.

(7) The Cu alloy film for a display device according to any one of Items (4) to (6), in which the underlayer has a thickness of 10 nm or more and 200 nm or less.

(8) A display device which includes thin film transistors each including the Cu alloy film for a display device according to any one of Items (1) to (7).

(9) The display device according to Item (8), wherein the thin film transistors have a bottom-gate structure and include gate electrodes and scanning lines each including the Cu alloy film for a display device.

The display device is preferably the display device according to Item (8), in which the thin film transistors have a bottom-gate structure and include gate electrodes and scanning lines each composed of the Cu alloy film for a display device.

(10) The display device according to Item (8) or (9), which is a flat panel display.

(11) A Cu alloy sputtering target including a Cu alloy containing one or more elements selected from the group consisting of Ti, Al, and Mg in a total content of 0.1 to 10.0 atomic percent.

The Cu alloy sputtering target is preferably a Cu alloy sputtering target composed of a Cu alloy containing one or more elements selected from the group consisting of Ti, Al, and Mg in a total content of 0.1 to 10.0 atomic percent.

The present invention further includes a display device including thin film transistors each using the Cu alloy film, of which a flat panel display typified by a liquid crystal display or organic electroluminescent (EL) display is preferred.

In the display device in a preferred embodiment, the thin film transistors have a bottom-gate structure in which the Cu alloy film is used in gate electrodes and scanning lines, and the Cu alloy film is in direct contact with a glass substrate. The Cu alloy film in this embodiment further sufficiently exhibits its advantageous effects.

### ADVANTAGEOUS EFFECTS OF INVENTION

The present invention provides a display device having a Cu alloy film which has a low electric resistance and thereby allows the display device (such as a liquid crystal display) to have a larger screen-size and to operate at higher frequencies. The Cu alloy film according to the present invention excels both in adhesion to a transparent substrate (glass substrate) and in etching properties, and, when adopted to a display device (such as a liquid crystal display), especially to gate electrodes and scanning lines of TFTs in the display device, can be deposited on a transparent substrate (glass substrate) without the formation of the Mo-containing underlayer. Thus, the Cu alloy film can gives a display device having high performance at lower production cost while avoiding the need of the Mo-containing underlayer.

### BRIEF DESCRIPTION OF DRAWINGS

FIG. 1 is a schematic enlarged sectional view showing the structure of a typical liquid crystal display to which an amorphous silicon TFT array substrate is adopted.

FIG. 2 is a schematic sectional view showing the structure of the TFT array substrate relating to an embodiment of the present invention and is an enlarged view of the essential part A of FIG. 1.

FIG. 3 is a schematic diagram sequentially illustrating an exemplary manufacturing process for the TFT array substrate shown in FIG. 2.

FIG. 4 is a schematic diagram sequentially illustrating the exemplary manufacturing process for the TFT array substrate shown in FIG. 2.

FIG. 5 is a schematic diagram sequentially illustrating the exemplary manufacturing process for the TFT array substrate shown in FIG. 2.

FIG. 6 is a schematic diagram sequentially illustrating the exemplary manufacturing process for the TFT array substrate shown in FIG. 2.

FIG. 7 is a schematic diagram sequentially illustrating the exemplary manufacturing process for the TFT array substrate shown in FIG. 2.

FIG. 8 is a schematic diagram sequentially illustrating the exemplary manufacturing process for the TFT array substrate shown in FIG. 2.

FIG. 9 is a schematic diagram sequentially illustrating the exemplary manufacturing process for the TFT array substrate shown in FIG. 2.

FIG. 10 is a schematic diagram sequentially illustrating the exemplary manufacturing process for the TFT array substrate shown in FIG. 2.

FIG. 11 is a graph showing how the film adhesion rate varies depending on the heat treatment temperature in Cu alloy films containing 0.1 atomic percent of X (Ti, Al, or Mg).

FIG. 12 is a graph showing how the film adhesion rate varies depending on the heat treatment temperature in Cu alloy film containing 2.0 atomic percent of X (Ti, Al, or Mg).

FIG. 13 is a graph showing how the film adhesion rate varies depending on the heat treatment temperature in Cu alloy films containing 5.0 atomic percent of X (Ti, Al, or Mg).

FIG. 14 is a graph showing how the electric resistivity varies depending on the heat treatment temperature in Cu alloy films containing 0.1 atomic percent of X (Ti, Al, or Mg).

FIG. 15 is a graph showing how the electric resistivity varies depending on the heat treatment temperature in Cu alloy films containing 2.0 atomic percent of X (Ti, Al, or Mg).

FIG. 16 is a graph showing how the electric resistivity varies depending on the heat treatment temperature in Cu alloy films containing 5.0 atomic percent of X (Ti, Al, or Mg).

FIG. 17 is a graph showing how the adhesion rate varies depending on the content of the alloy element in specimens (Cu multilayer films) immediately after film deposition.

FIG. 18 is a graph showing how the adhesion rate varies depending on the content of the alloy element in specimens (Cu multilayer films) after a heat treatment.

FIG. 19 is a graph showing how the adhesion rate varies depending on the oxygen content in a sputtering gas (Ar+O₂) for the deposition of the underlayer in Cu multilayer films.

FIG. 20 is a graph showing how the adhesion rate varies depending on the thickness of the underlayer in the Cu multilayer films.

FIG. 21 is a graph showing how the electric resistivity varies depending on the heat treatment temperature in Cu multilayer films containing 2.0 atomic percent of X (Ti, Al, or Mg).

FIG. 22 is a graph showing how the electric resistivity varies depending on the heat treatment temperature in Cu multilayer films containing 5.0 atomic percent of X (Ti, Al, or Mg).

FIG. 23 is a graph showing how the electric resistivity varies depending on the heat treatment temperature in Cu multilayer films containing 10.0 atomic percent of X (Ti, Al, or Mg).

FIG. 24 is a schematic sectional view showing what is the undercutting as measured in experimental examples.

### DESCRIPTION OF EMBODIMENTS

The present inventors made intensive investigations to provide a Cu alloy film having satisfactory adhesion to a glass substrate (preferably further having satisfactory etching properties) while maintaining a low electric resistance, a feature of Cu-based materials; and to provide a display device using the Cu alloy film in TFTs.

Initially, the present inventors have considered that, for increasing the adhesion between a Cu-based electrode/interconnection and a glass substrate, it is preferred to form a chemical binding between an element constituting the Cu-based electrode/interconnection and an element constituting the glass substrate (hereinafter referred to as “glass-substrate-constituting element), in which, more specifically, chemical adsorption is induced or an interfacial reaction layer is formed. This is probably because the “chemical binding due to occurrence of chemical adsorption or formation of an interfacial reaction layer” shows a higher binding energy (binding power) and thereby exhibits a stronger adhesion at the interface than that of a “physical binding due typically to physical adsorption”.

It is, however, difficult to form a chemical binding between Cu constituting the Cu-based electrode/interconnection and the glass-substrate-constituting element. Accordingly, the present inventors have hit upon an idea that a Cu alloy containing an element easily forming a chemical binding with the glass substrate is used in the Cu-based electrode/interconnection; and allowing the alloy element to form a chemical binding with the glass-substrate-constituting element. Based on this idea, the present inventors have made investigations on a specific technique to achieve this.

As a result, the present inventors have found that a Cu alloy film containing one or more elements selected from the group consisting of Ti, Al, and Mg as an alloy element will do as a Cu alloy film which works as an interconnection to be in direct contact with the glass substrate. This Cu alloy film shows higher adhesion to the glass substrate, probably because the glass substrate is composed of a mixture of various metal oxides and contains a large amount of oxygen as a constitutional element; and a chemical binding is formed between the oxygen (e.g., oxygen of SiO₂, a main component of the glass substrate) and the alloy element Ti, Al, or Mg.

Specifically, Al and Mg react with SiO₂ to form Si—Al—O and Si—Mg—O multi-component oxides, respectively, in a system at a temperature of 20° C. to 300° C. and a pressure of 1 atmosphere. Ti reacts with SiO₂ to form nitrides of TiSi or TiSi₂ in a system at a temperature of 20° C. to 300° C. and a pressure of 1 atmosphere.

These elements dramatically improve the adhesion to the glass substrate, also probably because they have diffusion coefficients in Cu higher than the self-diffusion coefficient of Cu, and, even when present in a small amount, they diffuse and concentrate at the interface with the glass substrate as a result of heating after the film deposition and react with SiO₂ at the interface to form chemical bindings.

To exhibit the advantageous effects sufficiently, the Cu alloy film should contain one or more elements selected from the group consisting of Ti, Al, and Mg (hereinafter these elements are generically also referred to as element “X”) in a total content of 0.1 atomic percent or more. Hereinafter the Cu alloy film according to the present invention having this configuration is also referred to as a “Cu—X-containing alloy film”. These elements are contained preferably in a total content of 0.2 atomic percent or more, more preferably in a total content of 0.5 atomic percent or more, and furthermore preferably in a total content of 1.0 atomic percent or more.

The higher the content of X is, the better from the viewpoint of improving the adhesion to the glass substrate. However, an excessively high content of X may cause the Cu alloy film to have a higher electric resistance, and the total content of X should be controlled to be 10 atomic percent or less (preferably 5.0 atomic percent or less). The total content of X is more preferably 2.0 atomic percent or less, for providing a further lower electric resistance.

The Cu—X-containing alloy film can have dramatically excellent adhesion through a heat treatment after the film deposition. This is because the heat treatment (heat energy) after the film deposition accelerates the concentrating (enrichment) of the alloy element (X) at the interface with the glass substrate and thereby accelerates the formation of chemical bindings at the interface.

The heat treatment acts so as to improve the adhesion more effectively with an elevating temperature and with a longer holding time of the heat treatment. However, the heat treatment temperature should be equal to or lower than the upper temperature limit of the glass substrate, and an excessively long holding time may cause lower productivity of the display device (such as a liquid crystal display). Accordingly, the heat treatment is preferably performed at a temperature in the range of 350° C. to 450° C. for a holding time in the range of 30 to 120 minutes. This heat treatment also effectively acts so as to allow the Cu—X-containing alloy film to have a lower electric resistivity and is also desirable from the viewpoint of achieving a low electric resistance.

The heat treatment may be a heat treatment performed in order to further improve the adhesion or may be one in which the thermal hysteresis after the deposition of the Cu—X-containing alloy film satisfies the above-specified conditions on temperature and time.

The Cu—X-containing alloy film contains X in the specific amount, with the remainder including Cu and inevitable impurities.

For imparting other properties, the Cu—X-containing alloy film may further contain one or more other elements within ranges not adversely affecting the operation of the present invention. Specifically, when adopted to gate electrodes and scanning lines of TFTs typically having a bottom-gate structure, the Cu—X-containing alloy film should also excel in properties such as “oxidation resistance (stability of contact with the ITO film)” and “corrosion resistance” in addition to the adhesion to the glass substrate. The Cu—X-containing alloy film may be required to have a further lower electric resistivity. In addition, when adopted to source electrodes and/or drain electrodes and signal lines of TFTs, the Cu—X-containing alloy film should excel in “adhesion to the insulating film (SiN film)” in addition to the above-mentioned properties such as “oxidation resistance (stability of contact with the ITO film)”.

In these cases, the Cu—X-containing alloy film can be a Cu alloy film of a multi-component system by adding one or more alloy elements effective for improving the properties such as “oxidation resistance (stability of contact with the ITO film)”, in addition to the alloy element (X).

The Cu—X-containing alloy film is preferably deposited through sputtering. The sputtering is a technique in which Ar or another inert gas is introduced into a vacuum, a plasma discharge is formed between the substrate and a sputtering target (hereinafter also referred to as “target”) to ionize the Ar gas, the ionized Ar collides against the target to beat atoms out of the target, and the atoms are deposited on the substrate to form a thin film. The sputtering can easily give a thin film more excellent in composition and in in-plane uniformity of the film thickness than thin films deposited through another technique such as ion plating, electron beam evaporation, or vacuum deposition. In addition, in the thin film deposited through the sputtering, the alloy element is uniformly dissolved to form a solid solution in an as-deposited state (i.e., in a state immediately after film deposition; hereinafter also referred to as “as-depo state”). The thin film can therefore effectively exhibit high-temperature oxidation resistance. The sputtering can be performed according to any sputtering process such as DC sputtering, RF sputtering, magnetron sputtering, or reactive sputtering, and conditions for the deposition of the thin film can be set as appropriate.

When the Cu—X-containing alloy film is deposited through the sputtering, the target is preferably a Cu—X-containing sputtering target composed of a Cu alloy containing one or more elements (X) selected from the group consisting of Ti, Al, and Mg in a total content of 0.1 to 10.0 atomic percent and having the same composition with that of the desired Cu—X-containing alloy film. This gives a Cu—X-containing alloy film having a desired composition while avoiding a deviation from the desired composition. In some sputtering target materials, the composition of the Cu alloy film deposited through sputtering may slightly differ from the composition of the sputtering target. However, the “difference (deviation)” in composition is approximately several percent or less, and a Cu alloy film having a given composition can be deposited by controlling the alloy composition of the sputtering target within ±10% of the desired composition.

The shape of the target includes any arbitrary shape (e.g., a rectangular plate shape, round plate shape, or toroidal plate shape) processed according to the shape and structure of the sputtering equipment.

Exemplary processes to prepare the target include a process of producing ingots composed of a Cu-based alloy through melting/casting, powder sintering, or spray forming, and forming the ingots into a target with a desired shape; and a process of producing a preform (intermediate before a final compact body) composed of a Cu-based alloy and densifying the preform into the compact body.

The present inventors also made intensive investigations to provide a Cu alloy film for a display device, which shows higher adhesion to a glass substrate, a low electric resistivity, and excellent etching properties. As a result, they have found that the object can be achieved by using, as the Cu alloy film, (I) a Cu multilayer film (hereinafter also referred to as “Cu multilayer film (I)”) which has a multilayer structure including an underlayer including oxygen and a Cu alloy containing one or more elements selected from the group consisting of Ti, Al, and Mg in a total content of 0.2 to 10.0 atomic percent, and an upper layer being substantially free from oxygen, in which the underlayer is in contact with the substrate; or (II) a Cu multilayer film (hereinafter also referred to as “Cu multilayer film (II)”) which has a multilayer structure including:

an underlayer composed of oxygen and a Cu alloy containing one or more elements selected from the group consisting of Ti, Al, and Mg in a total content of 0.2 to 10.0 atomic percent, and
an upper layer being substantially free from oxygen, being composed of pure Cu or a Cu alloy, the Cu alloy containing Cu as a main component and having an electric resistivity lower than that of the underlayer, in which the underlayer is in contact with the substrate;
   (the Cu multilayer film (I) and Cu multilayer film (II) are also generically referred to as “Cu multilayer film”).

As used herein the phrase “containing Cu as a main component” refers to that Cu has the largest mass or number of atoms (atomicity) among elements constituting the material.

As used herein the term “underlayer” refers to a layer which is indirect contact with the substrate as mentioned above, and the term “upper layer” refers to a layer lying directly on the underlayer.

Initially, the alloy composition of the Cu multilayer films according to the present invention will be described below.

The underlayer of the Cu multilayer film (I) or of the Cu multilayer film (II) is a layer containing one or more elements (X) selected from the group consisting of Ti, Al, and Mg in a total content of 0.2 to 10.0 atomic percent. As is described above, the glass substrate is composed of a mixture of various metal oxides and contains a large amount of oxygen as a constitutional element. The Cu multilayer film shows higher adhesion to the glass substrate probably because chemical bindings are formed between this oxygen (for example, oxygen of SiO₂, a main component of the glass substrate) and the elements Ti, Al and Mg.

To exhibit the effects sufficiently and to further improve the adhesion in the Cu multilayer film according to the present invention, the underlayer should contain one or more elements (X) selected from the group consisting of Ti, Al, and Mg in a total content of 0.2 atomic percent or more. If the content of X is less than this range, the element X is insufficient in its absolute amount, thereby less concentrates at the interface with the glass substrate. The element X therefore less contributes to the formation of chemical bindings at the interface, and the Cu multilayer film may not satisfactorily exhibit further higher adhesion. The element X is contained preferably in a total content of 0.5 atomic percent or more, and more preferably in a total content of 1.0 atomic percent or more. In contrast, if the content of X is excessively high, the Cu multilayer film itself has a higher electric resistance, although it shows higher adhesion at the interface with the glass substrate. The Cu multilayer film may have a higher etching rate than that of a pure Cu film. In the case of the Cu multilayer film (II) whose upper layer is a film of pure Cu or a Cu alloy containing Cu as a main component, the underlayer is susceptible to a phenomenon of undercut in which the underlayer is more excessively etched during etching than the upper layer (pure Cu film) is, because, when immersed in an etchant, the underlayer shows a larger variation in corrosion resistance than the film (upper layer) of pure Cu or a Cu alloy containing Cu as a main component. For this reason, the total content of X is controlled to be 10 atomic percent or less. The total content of X is preferably 5.0 atomic percent or less, from the viewpoint of providing a further lower electric resistance.

The underlayer of the Cu multilayer film (I) or of the Cu multilayer film (II) may be a layer containing the specific amount of X (alloy element), with the remainder being Cu and inevitable impurities. The underlayer may further contain one or more other elements in order to impart other properties, within ranges not adversely affecting the operation of the present invention. Specifically, the underlayer can be a Cu alloy film of a multi-component system, which further contains one or more alloy elements effective for the improvement of properties such as “oxidation resistance (stability of contact with the ITO film)” and “corrosion resistance”, in addition to the alloy element (X).

The underlayer of the Cu multilayer film (I) and the underlayer of the Cu multilayer film (II) contain oxygen. The presence of oxygen allows the chemical binding to be formed more firmly. The element (X) is effective for the formation of the chemical binding with oxygen in the glass substrate, as described above. The formation of the chemical binding requires energy at a certain level. In general, a Cu alloy film containing the element X, if merely deposited on a glass substrate through sputtering, may not have the energy at a sufficient level and may fail to exhibit further higher adhesion. According to the present invention, therefore, the underlayer of the Cu multilayer film to be in contact with the substrate is an oxygen-containing layer.

An oxygen-containing layer as the underlayer may be formed typically by a process of forming the layer through sputtering with a sputtering gas having an oxygen content within a certain range. This process is a kind of reactive sputtering and contributes to higher adhesion, probably because “oxygen plasma assist” accelerates the chemical binding between the alloy element (X) and the oxygen in the glass substrate.

The sputtering gas has an oxygen content of preferably 1 percent by volume or more and less than 20 percent by volume. The sputtering gas, if having an oxygen content of less than 1 percent by volume, may not sufficiently accelerate the chemical binding between the alloy element (X) and oxygen in the glass substrate, often resulting in insufficiently improved adhesion. The oxygen content is more preferably 5.0 percent by volume or more.

With an increasing oxygen content in the sputtering gas, the chemical binding is more accelerated to further improve the adhesion. However, the effect of improving the adhesion to the substrate is saturated at an oxygen content of 20 percent by volume or more. In contrast, a higher oxygen content of the sputtering gas may lower the sputtering yield and thereby lower the productivity of the deposition of the Cu alloy film. Accordingly, the sputtering gas has an oxygen content of preferably 20 percent by volume or less (more preferably 10 percent by volume or less). The oxygen content of the sputtering gas is not limited from the viewpoint of reducing the interconnection resistivity, because, when sputtering is performed with an inert gas mixed with oxygen, the resulting oxygen-containing Cu alloy interconnection shows a not so much increased electric resistivity.

The sputtering gas can for example be a gaseous mixture containing Ar and oxygen in the above-specified content. Hereinafter description will be made while taking Ar as example, but another inert gas (noble gas) such as Xe will also do.

The underlayer has an oxygen content of typically preferably 0.5 to 30 atomic percent. To accelerate the chemical binding, the underlayer has an oxygen content of preferably 0.5 atomic percent or more, more preferably 1 atomic percent or more, furthermore preferably 2 atomic percent or more, and especially preferably 4 atomic percent or more. In contrast, the underlayer, if having an excessively high oxygen content and thereby showing excessively high adhesion, may leave a residue after wet etching, thus repulsing in insufficient wet etching properties. Such an underlayer having an excessively high oxygen content may cause the Cu alloy film to have a higher electric resistance. In consideration of these points, the underlayer has an oxygen content of preferably 30 atomic percent or less, more preferably 20 atomic percent or less, furthermore preferably 15 atomic percent or less, and especially preferably 10 atomic percent or less.

The upper layer of the Cu multilayer film (I) and the upper layer of the Cu multilayer film (II) preferably ones being substantially free from oxygen from the viewpoint of reducing the electric resistance. The upper layers preferably have an oxygen content of at most not exceeding the upper limit of the oxygen content of the underlayer (for example 0.5 atomic percent). The upper layers have an oxygen content of more preferably 0.1 atomic percent or less, furthermore preferably 0.05 atomic percent or less, especially preferably 0.02 atomic percent or less, and most preferably O atomic percent.

The upper layer of the Cu multilayer film (II) is composed of pure Cu or a Cu alloy, the Cu alloy containing Cu as a main component and having an electric resistivity lower than that of the underlayer. The presence of the upper layer allows the Cu multilayer film (II) to have an interconnection electric resistivity further lower than that of the Cu multilayer film (I).

The “Cu alloy containing Cu as a main component and having an electric resistivity lower than that of the underlayer” is not limited, as long as being one which is suitably controlled in the type and/or content of alloy element(s) so as to have an electric resistivity lower than that of the underlayer including the Cu alloy containing one or more elements (X) for improving adhesion. The element having a low electric resistivity (element having an electric resistivity approximately as low as pure Cu) can be easily selected from among known elements with reference typically to literature data (electric resistivities). The alloy element adaptable to the upper layer is not always limited to such elements having low electric resistivities, because even an element having a high electric resistivity can contribute to the reduction of the electric resistivity when used in a small content (approximately about 0.05 to 1 atomic percent). Specifically, exemplary Cu alloys preferably usable herein include Cu-0.5 atomic percent Ni, Cu-0.5 atomic percent Zn, and Cu-0.3 atomic percent Mn.

The underlayer of the Cu multilayer film (I) or of the Cu multilayer film (II) has a thickness of preferably 10 nm or more and 200 nm or less. To ensure the absolute content of the alloy element which forms a chemical binding with oxygen, the underlayer preferably has a thickness of 10 nm or more. The underlayer, if having a thickness lower than this range, should have a total content of the alloy element (X) of, for example, more than 10 atomic percent so as to compensate the absolute content of the alloy element. However, such an excessively high content of the alloy element may often cause the Cu multilayer film to have a higher electric resistivity and/or impaired etching properties, thus being undesirable. The underlayer has a thickness of more preferably 20 nm or more.

In contrast, the underlayer, if having an excessively large thickness, may impede the control of the interconnection profile to be a desired tapered shape. Particularly, the oxygen-containing Cu alloy film has an etching rate higher than that of the Cu alloy film being substantially free from oxygen and thereby often suffer from an undercut during etching, and this may impede the pattering of the interconnection into a desired tapered shape. In addition, the underlayer, if having an excessively large thickness, works as an interconnection section having a high electric resistivity and occupies a relatively large portion of the Cu multilayer film, and this may cause the interconnection to have a higher effective interconnection resistance. For these reasons, the underlayer has a thickness of preferably 200 nm or less, more preferably less than 100 nm, and furthermore preferably 50 nm or less.

The Cu multilayer films can have remarkably satisfactory adhesion by subjecting to a heat treatment after the film deposition, as with the Cu—X-containing alloy films. The heat treatment also effectively acts to reduce the electric resistivity and is preferable from the viewpoint of providing a low electric resistance. However, the heat treatment should be performed at a temperature equal to or lower than the upper temperature limit of the glass substrate, and the heat treatment, if performed for an excessively long holding time, may cause insufficient productivity of the display device (such as a liquid crystal display). From these viewpoints, the heat treatment is preferably performed at a temperature in the range of 350° C. to 450° C. for a holding time in the range of 30 to 120 minutes. The heat treatment may be a heat treatment performed in order to further improve the adhesion or may be one in which the thermal hysteresis after the deposition of the Cu multilayer film satisfies the above-specified conditions on temperature and time.

The Cu multilayer film is preferably deposited through sputtering. While the details of the sputtering are as described in the deposition of the Cu—X-containing alloy film, the Cu multilayer film can be deposited through sputtering in the following method.

Specifically, when the Cu multilayer film is formed or deposited as the Cu multilayer film (I), the underlayer and the upper layer are deposited as Cu alloy films having the same alloy composition but differing in the presence or absence of oxygen to form a multilayer structure. In this case, the Cu multilayer film (I) may be formed by depositing the underlayer using a sputtering gas composed of a gaseous mixture containing Ar and O₂; and depositing the upper layer using a sputtering gas composed of Ar alone, while each using a Cu alloy target having a specific composition as the sputtering target.

When the Cu multilayer film is formed as the Cu multilayer film (II), the underlayer is deposited as a Cu alloy film having a given composition, and the upper layer is deposited typically as a pure Cu film. In this case, the Cu multilayer film (II) is formed, for example, by depositing the underlayer using a Cu alloy target (for the underlayer) having a specific composition and using a sputtering gas composed of a gaseous mixture of Ar and O₂; and depositing the upper layer using a pure Cu target (for the upper layer) and using a sputtering gas composed of Ar alone.

In a preferred embodiment, the Cu alloy films according to the present invention (Cu—X-containing alloy films and Cu multilayer films) are used in, of TFTs:

source electrodes and/or drain electrodes and signal lines, and/or,

gate electrodes and scanning lines. In a further preferred embodiment, the TFTs have a bottom-gate structure, and the Cu—X-containing alloy film or Cu multilayer film is used in gate electrodes and scanning lines of the TFTs and is in direct contact with the glass substrate. According to this embodiment, the Cu alloy film can exhibit its characteristic properties further sufficiently.

When two or more plies of the Cu—X-containing alloy film or Cu multilayer film are used at two or more points in the source electrode and/or drain electrode and signal line, and/or, gate electrode and scanning line, the multiple plies of the Cu—X-containing alloy film or Cu multilayer film may have the same composition or may have different compositions as long as being within the specific range.

A manufacturing method of the TFT array substrate according to this embodiment as illustrated in FIG. 2 will be described with reference to the attached drawings. The same components in FIGS. 3 to 10 as the components in FIG. 2 have the same reference signs, respectively.

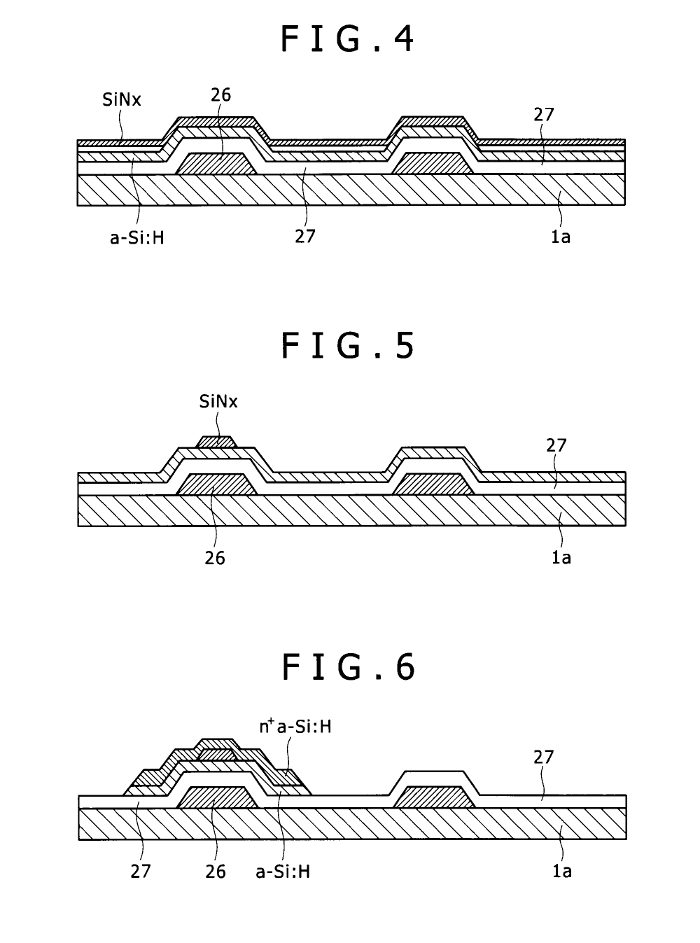

Initially, with reference to FIG. 3, a Cu—X-containing alloy film or Cu multilayer film is deposited through sputtering to a thickness of about 200 nm on a glass substrate (transparent substrate) 1a. The resulting film is patterned to form a gate electrode 26 and a scanning line 25. In this process, the side faces of the alloy film are preferably etched so as to be tapered at an inclination of about 30 degrees to 60 degrees, in order to improve the coverage of a gate insulating film 27 illustrated in FIG. 4 mentioned below.

Next, with reference to FIG. 4, a gate insulating film (SiN film) 27 having a thickness of about 300 nm is deposited typically through plasma chemical vapor deposition (plasma CVD). The film deposition through plasma CVD may be performed at a temperature of about 350° C. Next, on the gate insulating film 27, are sequentially deposited a hydrogenated amorphous silicon film (a-Si:H) having a thickness of about 50 nm and a silicon nitride film (SiNx) having a thickness of about 300 nm.

Subsequently, with reference to FIG. 5, the silicon nitride film (SiNx) is patterned through back exposure using the gate electrode 26 as a mask, to form a channel protecting film. With reference to FIG. 6, an n⁺-type hydrogenated amorphous silicon film (n⁺a-Si:H) doped with phosphorus and having a thickness of about 50 nm is deposited thereon, and the hydrogenated amorphous silicon film (a-Si:H) and the n⁺-type hydrogenated amorphous silicon film (n⁺a-Si:H) are patterned.

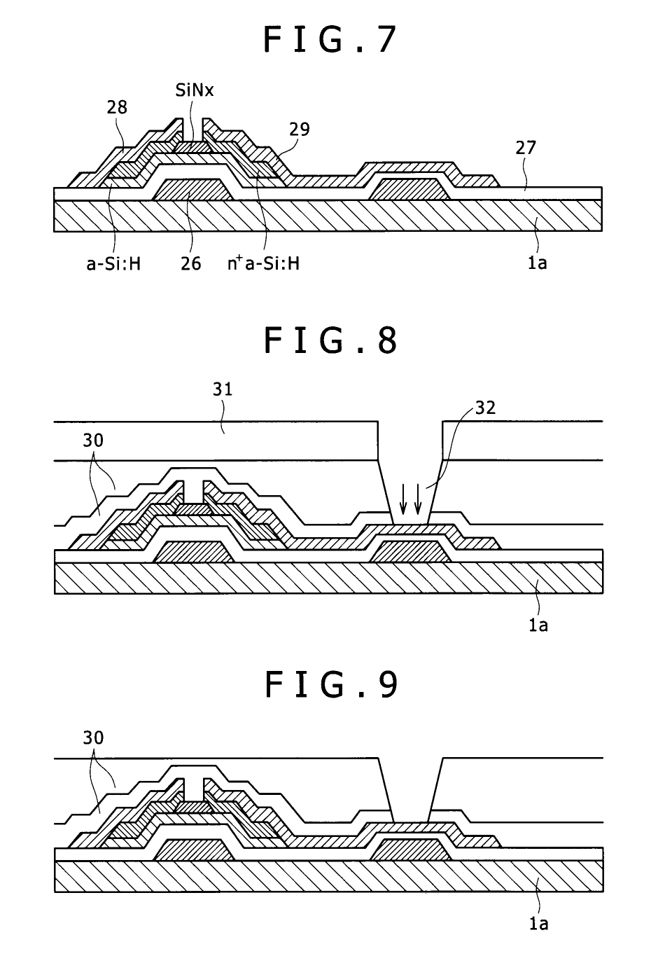

Then, with reference to FIG. 7, a Cu—X-containing alloy film or Cu multilayer film having a thickness of about 300 nm is deposited through sputtering, patterned, and thereby yields a source electrode 28 as an integrated whole with a signal line; and a drain electrode 29 to be in direct contact with a pixel electrode (transparent conductive film) 5.

Next, with reference to FIG. 8, a protective film (passivation film) is formed as a silicon nitride film 30 by depositing the same to a thickness of typically about 300 nm typically using plasma CVD equipment. The film deposition in this process is performed at a temperature of typically about 250° C. After covered by a photoresist layer 31 formed thereon, the silicon nitride film 30 is patterned to form a contact hole 32 penetrating the silicon nitride film 30 typically through dry etching. Simultaneously with this, a contact hole (not shown) is formed in a portion on the gate electrode at an end of the panel, which portion is to be connected to a TAB (tape automated bonding).

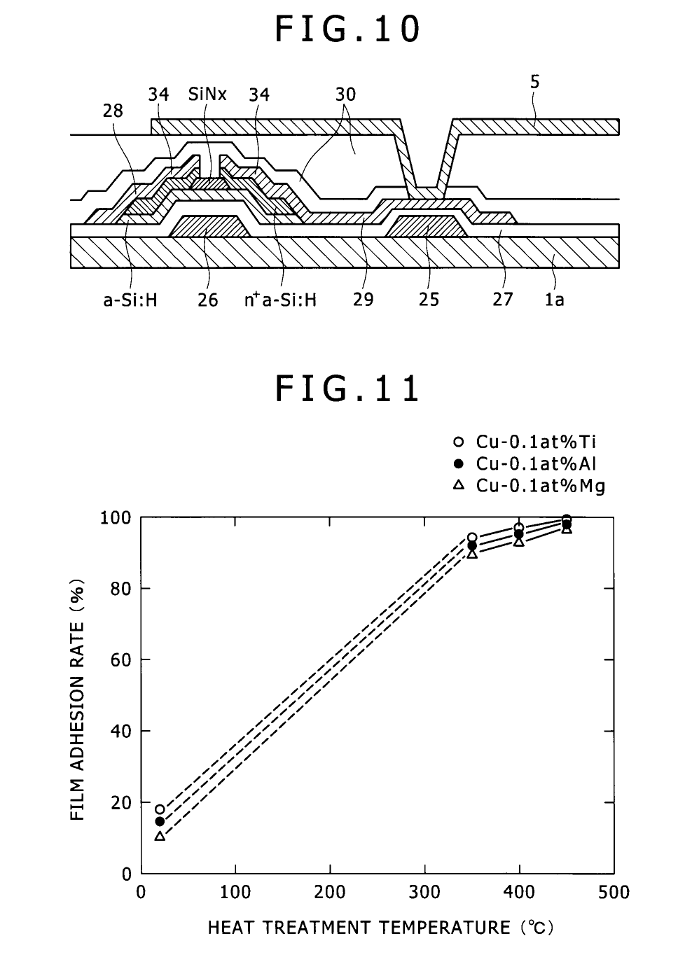

In addition, with reference to FIG. 9, an ashing process typically with oxygen plasma is performed, and the photoresist layer 31 is then removed using a remover typically of an amine compound. Finally, with reference to FIG. 10, an ITO film having a thickness of typically about 40 nm is deposited, patterned through wet etching, and thereby yields a pixel electrode (transparent conductive film) 5.

In the above embodiment, the ITO film is used as the pixel electrode (transparent conductive film) 5, but an IZO film (InOx-ZnOx conductive oxide film) will also do. A polysilicon is also usable as the active semiconductor layer instead of the amorphous silicon.

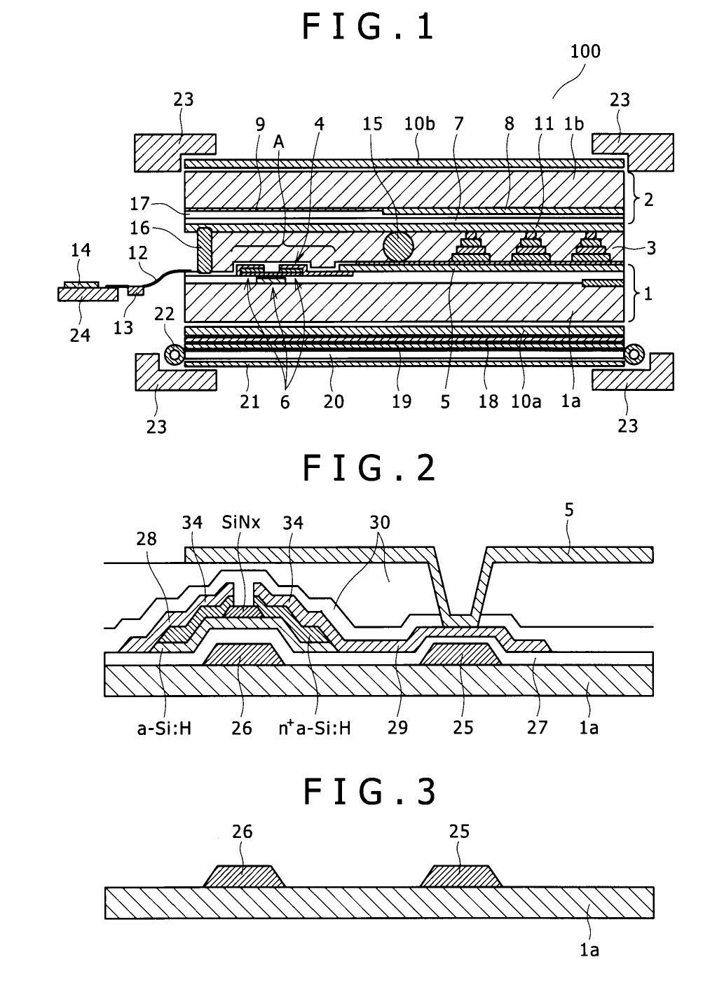

A liquid crystal display (display device) as illustrated in FIG. 1 may be manufactured according to a customary method using the above-prepared TFT array substrate.

### EXAMPLES

The present invention will be illustrated in further detail with reference to several experimental examples below. It should be noted, however, that these examples are never intended to limit the scope of the present invention; various alternations and modifications may be made without departing from the scope and spirit of the present invention and all fall within the scope of the present invention.

### Example 1

To evaluate adhesion between a Cu alloy film and a glass substrate, peel tests using an adhesive tape were performed in the following method.

(Preparation of Specimens)

Initially, a pure Cu film, a pure Mo film, and a series of Cu alloy films having the compositions given in Table 1 were deposited to a thickness of 300 nm on a glass substrate (Eagle 2000 supplied by Corning Inc., having a diameter of 100 mm and a thickness of 0.7 mm) through DC magnetron sputtering under film deposition conditions as mentioned below at room temperature. After deposition, the films were subjected to a heat treatment of holding at 350° C. in a vacuum atmosphere for 30 minutes and thereby yielded adhesion evaluation specimens.

The pure Cu film and the pure Mo film were deposited using a pure Cu sputtering target and a pure Mo sputtering target, respectively. The Cu alloy films having different compositions were deposited each using, as a sputtering target, a pure Cu sputtering target on which a chip containing another element than Cu was mounted, or a series of Cu—X binary alloy targets having different compositions and being prepared by vacuum melting.

(Film Deposition Conditions)

Back Pressure: 1.0×10⁻⁶ Torr or less

Ar Gas Pressure: 2.0×10⁻³ Torr

Ar Gas Flow Rate: 30 sccm

Sputtering Power: 3.2 W/cm²

Electrode-to-electrode Distance: 50 mm

Substrate Temperature: room temperature

The compositions of the deposited Cu alloy films were identified through quantitative analyses with an inductively coupled plasma (ICP)-emission spectrophotometer (the ICP Atomic Emission Spectrophotometer “Model ICP-8000” supplied by Shimadzu Corporation).

(Evaluation of Adhesion to Glass Substrate)

Slits were formed on a surface of the deposited film of each of the specimens (the surface of the pure Cu film, the pure Mo film, or the Cu alloy film) with a cutter knife to form cross cuts at intervals of 1 mm. Next, a black polyester tape (supplied by 3M Corporation under the product number 8422B) was firmly affixed to the surface of the deposited film and peeled off at a stroke while the peeling angle of the tape was kept to 60 degrees. The number of cross cuts not peeled off by the tape was counted, and the ratio of this number to the total number of the cross cuts (film adhesion rate) was determined. The results are shown in Table 1.

TABLE 1

| | | Content of alloy element (atomic percent) | | | | | |
|---|---|---|---|---|---|---|---|
| | | 0 | 0.1 | 0.5 | 1.0 | 2.0 | 5.0 |
| Film | Pure Cu | 5.1 | — | — | — | — | — |
| composition | Pure Mo | 100.0 | — | — | — | — | — |
| | Cu—Au alloy | — | 6.7 | 26.7 | 38.7 | 45.3 | 56.4 |
| | Cu—Ir alloy | — | 5.3 | 13.3 | 13.3 | 25.3 | 40.1 |
| | Cu—Al alloy | — | 92.1 | 97.4 | 98.2 | 100.0 | 100.0 |
| | Cu—Mg alloy | — | 90.0 | 90.5 | 91.1 | 92.0 | 100.0 |
| | Cu—Ti alloy | — | 94.2 | 98.5 | 100.0 | 100.0 | 100.0 |
| | Cu—Nb alloy | — | 0 | 0 | 0 | 0 | 17.3 |
| | Cu—Mo alloy | — | 0 | 0 | 0 | 0 | 1.3 |
| | Cu—Fe alloy | — | 0 | 0 | 6.1 | 12.0 | 65.3 |

The numerals in the table represent film adhesion rates (%).

Table 1 demonstrates as follows. The pure Cu film has a film adhesion rate of about 5% and shows poor adhesion to the glass substrate. In contrast, the pure Mo film has a film adhesion rate of 100% and shows satisfactory adhesion to the glass substrate. The pure Mo film, however, has a demerit of having an electric resistance at room temperature considerably higher than that of the pure Cu.

Table 1 also demonstrates that, of the Cu alloy films, those containing another alloy element than X have film adhesion rates of approximately zero or as lower as less than 70%; but, in contrast to this, the Cu—X-containing alloy films containing X in a specific content have film adhesion rates of 90% or more and show satisfactory adhesion to the glass substrate.

### Example 2

A series of Cu—X-containing alloy films was deposited, and how the adhesion to a glass substrate (the film adhesion rate) varies depending on a heat treatment performed after film deposition was determined.

(Preparation of Specimens)

A series of Cu—X-containing alloy films (X is Al, Mg or Ti, the X content is 0.1 atomic percent, 2.0 atomic percent or 5.0 atomic percent) was deposited to a thickness of 300 nm on a glass substrate (Eagle 2000 supplied by Corning Inc., having a diameter of 100 mm and a thickness of 0.7 mm) through DC magnetron sputtering by the procedure of Example 1. Next, the following specimens were prepared:

(A) specimens as prepared in the above method (specimens in an as-deposited state),
(B) specimens after subjected to a heat treatment of holding at 350° C. in a vacuum atmosphere for 30 minutes,
(C) specimens after subjected to a heat treatment of holding at 400° C. in a vacuum atmosphere for 30 minutes, and
(D) specimens after subjected to a heat treatment of holding at 450° C. in a vacuum atmosphere for 30 minutes.

(Evaluation of Adhesion to Glass Substrate)

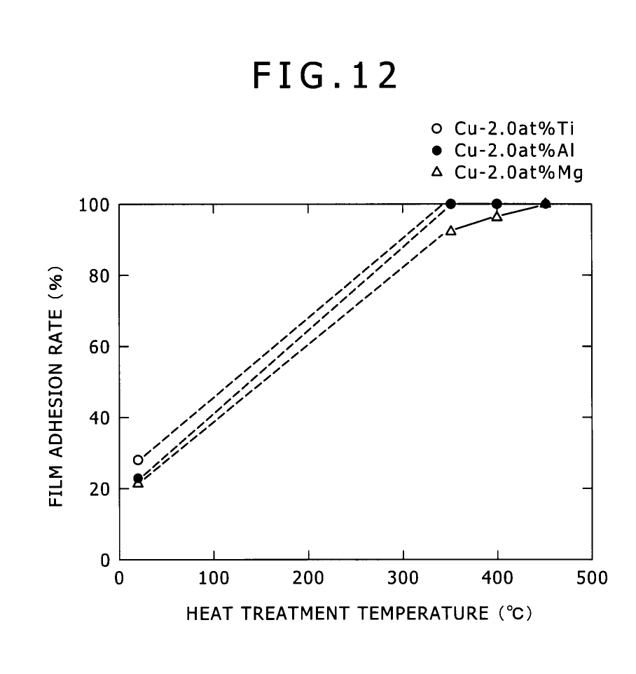

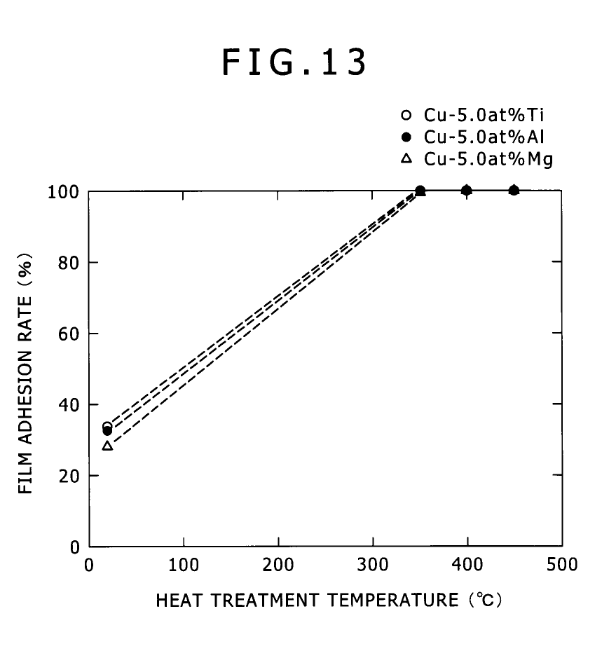

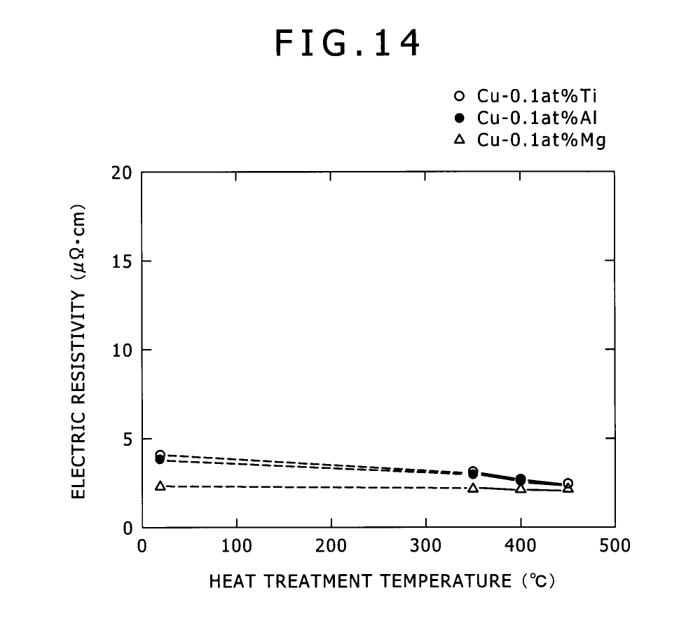

The adhesion to the glass substrate (the film adhesion rate) was evaluated by the procedure of Example 1. The results are summarized in FIGS. 11 to 13. FIG. 11 shows how the film adhesion rate varies depending on the heat treatment temperature in Cu alloy films containing 0.1 atomic percent of X (Ti, Al, or Mg). FIG. 12 shows how the film adhesion rate varies depending on the heat treatment temperature in Cu alloy film containing 2.0 atomic percent of X (Ti, Al, or Mg). FIG. 13 shows how the film adhesion rate varies depending on the heat treatment temperature in Cu alloy films containing 5.0 atomic percent of X (Ti, Al, or Mg).

FIGS. 11 to 13 demonstrate that the Cu—X-containing alloy films subjected to a heat treatment at a temperature of 350° C. or higher show remarkably excellent adhesion in terms of a film adhesion rate of 90% or more, as compared to corresponding Cu—X-containing alloy films in an as-deposited state, regardless of the type and content of the element X.

### Example 3

A series of Cu—X-containing alloy films was deposited, and the electric resistivities of the alloy films were measured and evaluated.

(Preparation of Specimens)

A series of Cu—X-containing alloy films (X is Al, Mg or Ti, the X content is 0.1 atomic percent, 2.0 atomic percent or 5.0 atomic percent) was deposited to a thickness of 300 nm on a glass substrate (Eagle 2000 supplied by Corning Inc., having a diameter of 100 mm and a thickness of 0.7 mm) through DC magnetron sputtering by the procedure of Example 1.

(Measurement of Electric Resistivity)

The above-prepared Cu—X-containing alloy films were processed into stripe patterns (electric resistivity testing patterns) having a width of 100 μm and a length of 10 mm through photolithography and wet etching, and the electric resistivities of the patterns were measured at room temperature by a direct-current four-point probe method using a prober.

The measurements of the electric resistivities were respectively made on the following specimens (stripe patterns) (a) to (d):

(a) specimens as prepared in the above method (stripe patterns in an as-deposited state),
(b) stripe patterns after subjected to a heat treatment of holding at 350° C. in a vacuum atmosphere for 30 minutes,
(c) stripe patterns after subjected to a heat treatment of holding at 400° C. in a vacuum atmosphere for 30 minutes, and
(d) stripe patterns after subjected to a heat treatment of holding at 450° C. in a vacuum atmosphere for 30 minutes.

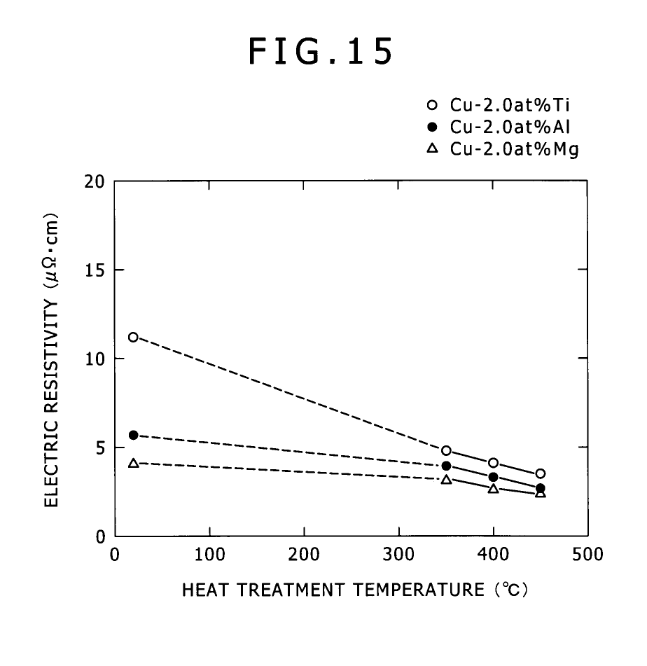

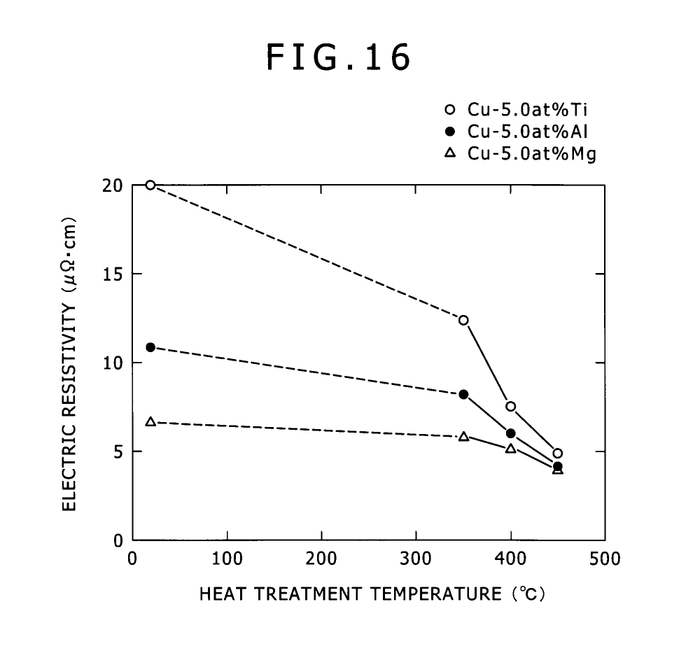

The results are summarized in FIGS. 14 to 16. FIG. 14 shows how the electric resistivity varies depending on the heat treatment temperature in Cu alloy films containing 0.1 atomic percent of X (Ti, Al, or Mg). FIG. 15 shows how the electric resistivity varies depending on the heat treatment temperature in Cu alloy films containing 2.0 atomic percent of X (Ti, Al, or Mg). FIG. 16 shows how the electric resistivity varies depending on the heat treatment temperature in Cu alloy films containing 5.0 atomic percent of X (Ti, Al, or Mg).

FIGS. 14 to 16 demonstrate that the Cu—X-containing alloy films in an as-deposited state have an increasing electric resistivity with an increasing content of the alloy element, and the Cu—X-containing alloy films having a content of X of 2.0 to 5.0 atomic percent show a relatively high electric resistivity; and that, in contrast to this, the Cu—X-containing alloy films after subjected to a heat treatment show lower electric resistivities, and the Cu—X-containing alloy films subjected to a heat treatment at a temperature of 350° C. or higher show dramatically lower electric resistivities than those of the corresponding Cu—X-containing alloy films in an as-deposited state.

### Example 4

Peel tests using various tapes as mentioned below were performed to evaluate the adhesion between a Cu multilayer film and a glass substrate.

(Preparation of Specimens)

As an underlayer, a series of Cu alloy films containing oxygen and one of Al, Mg and Ti in different contents, or a pure Cu film as a comparative example was deposited on a glass substrate (Eagle 2000 supplied by Corning Inc., having a diameter of 100 mm and a thickness of 0.7 mm) through DC magnetron sputtering under film deposition conditions as mentioned below. Next, a series of films having the same alloy compositions as those of the underlayers, except for being substantially free from oxygen was deposited as an upper layer on each underlayer, and thereby yielded Cu multilayer films. The Cu multilayer films each had a total thickness of 300 nm and a thickness of the underlayer of 50 nm. The sputtering target used herein was a pure Cu sputtering target, or a pure Cu sputtering target on which a chip of the additional alloy element (chip of pure metal of Al, Mg or Ti) was mounted.

A sputtering gas used for the deposition of the underlayers was a gaseous mixture of Ar and 5 percent by volume of O₂. A sputtering gas used for the deposition of the upper layers was a pure Ar gas. The mixing ratio between the Ar gas and the O₂ gas was set by the partial pressures of the Ar gas and the O₂ gas, and the ratio between the partial pressures was set by the ratio in flow rate between the Ar gas and the O₂ gas.

(Film Deposition Conditions)

Back Pressure: 1.0×10⁻⁶ Torr or less

Gas Pressure: 2.0×10⁻³ Torr

Gas Flow Rate: 30 sccm

Sputtering Power: 3.2 W/cm²

Electrode-to-electrode Distance: 50 mm

Substrate Temperature: room temperature

The compositions of the deposited Cu multilayer films were identified through quantitative analyses with an inductively coupled plasma (ICP)-emission spectrophotometer (the ICP Atomic Emission Spectrophotometer “Model ICP-8000” supplied by Shimadzu Corporation).

In addition, the presence of oxygen in the underlayers was verified through scanning electron microscopy-energy dispersive X-ray spectroscopy (SEM-EDX).

Specimens immediately after the film deposition in the above method (as-depo state) and specimens subjected to a heat treatment of holding at 350° C. in a vacuum atmosphere for 30 minutes after the film deposition were prepared as adhesion evaluation specimens.

(Evaluation of Adhesion to Glass Substrate)

Peel tests using tapes were performed in the following method to evaluate the adhesion to a glass substrate. Specifically, slits were formed on a surface of the deposited film of each of the specimens with a cutter knife to form cross cuts at intervals of 1 mm. The cross-cut slits were formed by marking off with a jig (stencil) so as to draw the same cross-cut shape on all the specimens. Next, a black polyester pressure-sensitive adhesive tape (supplied by 3M Corporation under the product number 8422B) was affixed to the surface of the deposited film using a laminator and then peeled off therefrom using a jig while the peeling angle of the tape was kept to 90 degrees. The number of cross cuts not peeled off by the tape was counted, and the ratio of this number to the total number of the cross cuts (adhesion rate; film adhesion rate) was determined.

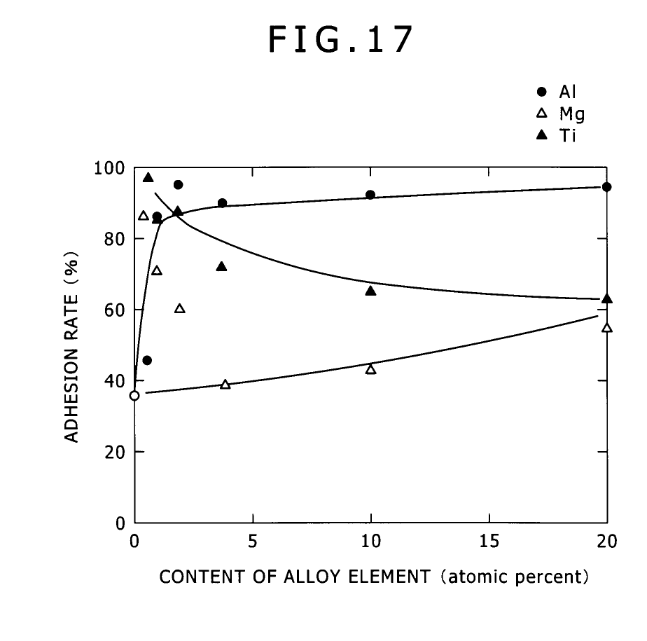

FIG. 17 shows how the adhesion rate varies depending on the content of the alloy element (Al, Mg or Ti) in the specimens immediately after film deposition. FIG. 17 demonstrates that the Cu multilayer films according to the present invention more excel in adhesion than the pure Cu film does. FIG. 17 also demonstrates that, among the Cu multilayer films, those of Cu—Al binary system containing Al as the alloy element show further excellent adhesion.

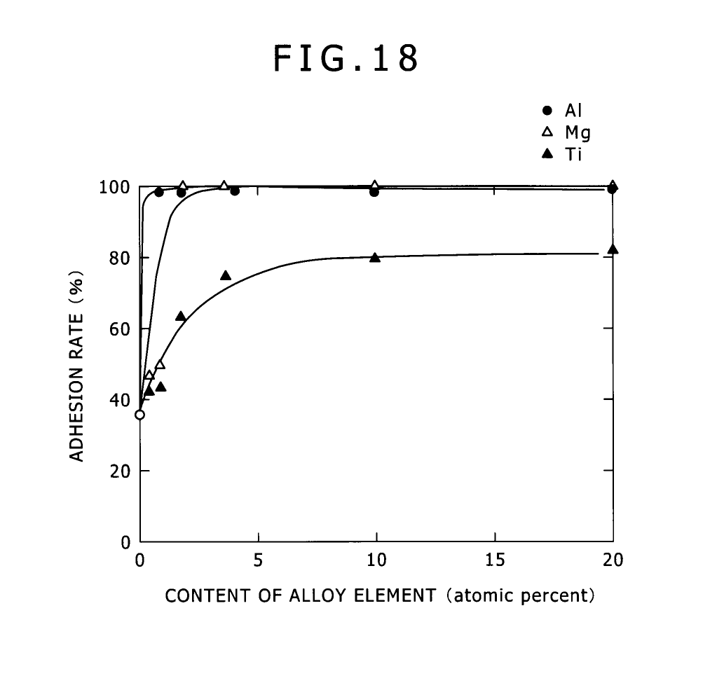

FIG. 18 shows how the adhesion rate varies depending on the content of the alloy element (Al, Mg or Ti) in the specimens after the heat treatment. FIG. 18 demonstrates that the heat treatment allows the specimens to have sufficiently higher adhesion than that of the corresponding specimens immediately after film deposition. FIG. 18 also demonstrates that the Cu multilayer films of Cu—Al binary system containing Al as the alloy element, and the Cu multi layer films of Cu—Mg binary system containing Mg as the alloy element have adhesion rates of approximately 100% and show excellent adhesion.

### Example 5

How the oxygen content of a sputtering gas for use in the deposition of the underlayer in a Cu multilayer film affects on the adhesion to a glass substrate was investigated.

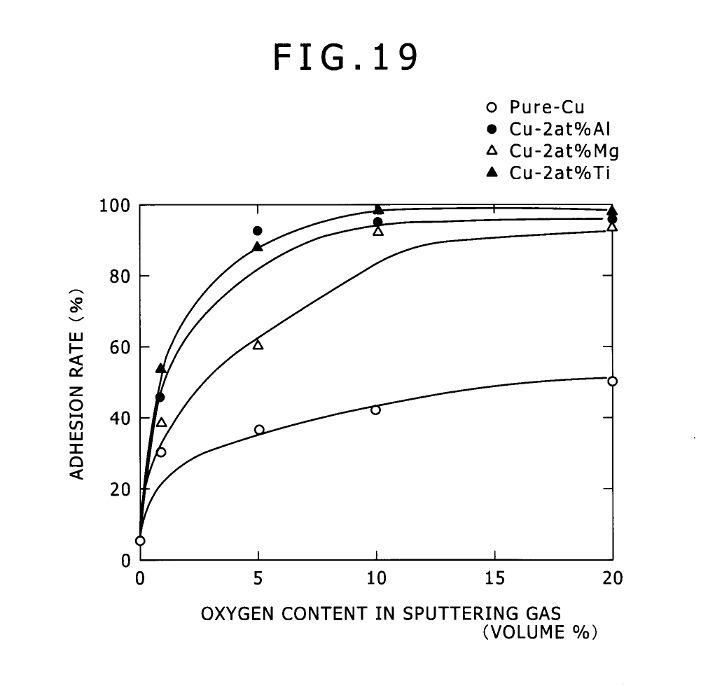

Cu multilayer films were deposited, from which adhesion evaluation specimens (specimens in an as-depo state) were prepared, and the adhesion of the specimens was evaluated by the procedure of Example 4, except for depositing, as the Cu multilayer film, a Cu-2 atomic percent Al alloy multilayer film, a Cu-2 atomic percent Mg alloy multilayer film, or a Cu-2 atomic percent Ti alloy multi layer film; and varying the oxygen content of the sputtering gas for the deposition of the underlayer. The results are shown in FIG. 19.

FIG. 19 shows how the adhesion rate varies depending on the oxygen content of the sputtering gas used in the deposition of the underlayer. FIG. 19 demonstrates that the Cu multilayer films containing any of the alloy elements (X) tend to show an increasing adhesion rate (to show improved adhesion) with an increasing oxygen content of the sputtering gas, although the absolute saturated adhesion rate varies depending on the type of the alloy element (X). FIG. 19 also demonstrates that the increase of the adhesion rate with an increasing oxygen content of the sputtering gas is saturated at an oxygen content of about 10 percent by volume.

### Example 6

How the thickness of the underlayer in a Cu multilayer film affects on the adhesion to a glass substrate was investigated.

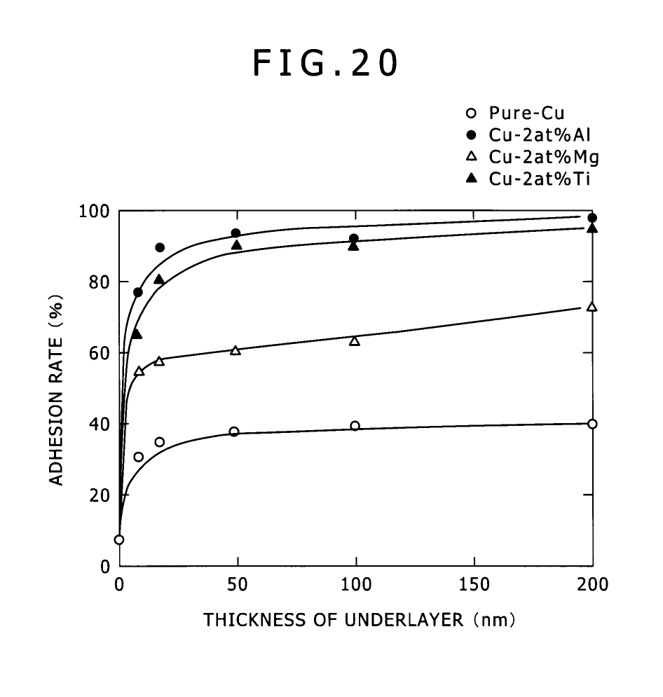

Cu multilayer films were deposited, from which adhesion evaluation specimens (specimens in an as-depo state) were prepared, and the adhesion of the specimens was evaluated by the procedure of Example 4, except for depositing, as the Cu multilayer film, a Cu-2 atomic percent Al alloy multilayer film, a Cu-2 atomic percent Mg alloy multilayer film, or a Cu-2 atomic percent Ti alloy multilayer film; and varying the thickness of the underlayer within the range of 10 to 200 nm in the respective Cu multilayer films (each having a total thickness of 300 nm). The results are shown in FIG. 20.

FIG. 20 shows how the adhesion rate varies depending on the thickness of the underlayer in the respective Cu multilayer films. FIG. 20 demonstrates that the Cu multilayer films tend to show an increasing adhesion rate (to show improved adhesion) with an increasing thickness of the underlayer, although the absolute saturated adhesion rate varies depending on the type of the alloy element (X). FIG. 20 also demonstrates that the increase of the adhesion rate with an increasing thickness of the underlayer is saturated at a thickness of the underlayer of about 100 nm.

### Example 7

How the type and content of the alloy element in a Cu multilayer film and the heat treatment temperature affect the electric resistance of the Cu multilayer film was investigated.

Cu multilayer films were deposited by the procedure of Example 4, from which electric resistivity evaluation specimens (specimens in an as-depo state, and specimens after a heat treatment) were prepared, except for depositing, as the Cu alloy multilayer film, a Cu— (2.0 atomic percent, 5.0 atomic percent, or 10.0 atomic percent) Al alloy multilayer film, a Cu— (2.0 atomic percent, 5.0 atomic percent, or 10.0 atomic percent) Mg alloy multilayer film, or a Cu— (2.0 atomic percent, 5.0 atomic percent, or 10.0 atomic percent) Ti alloy multilayer film; and except for not carrying out the heat treatment (i.e., the specimen was merely held at 25° C.) or varying the heat treatment temperature in the range of 350° C. to 450° C.

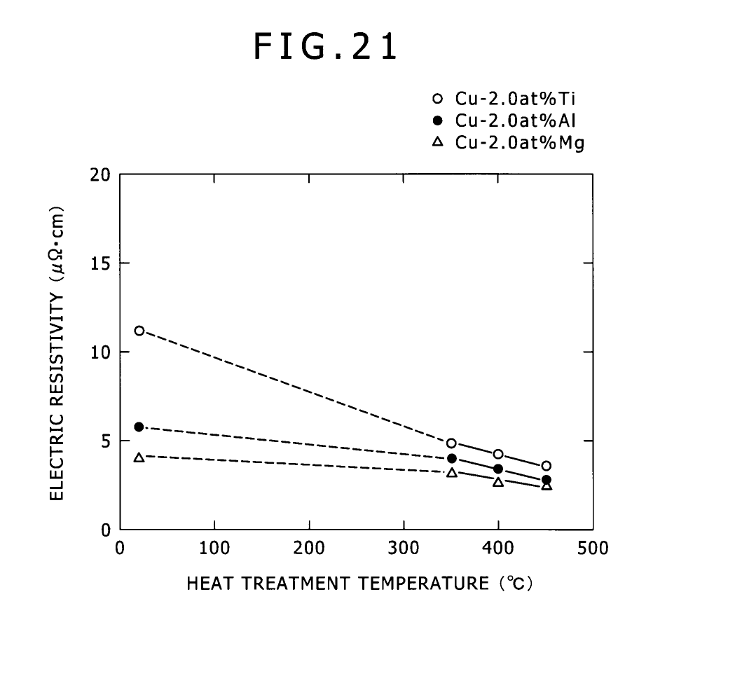

The specimens were processed into stripe patterns (electric resistivity testing patterns) having a width of 100 μm and a length of 10 mm through photolithography and wet etching, and the electric resistivities of the patterns were measured at room temperature by a direct-current four-point probe method using a prober. The results are shown in FIGS. 21 to 23.

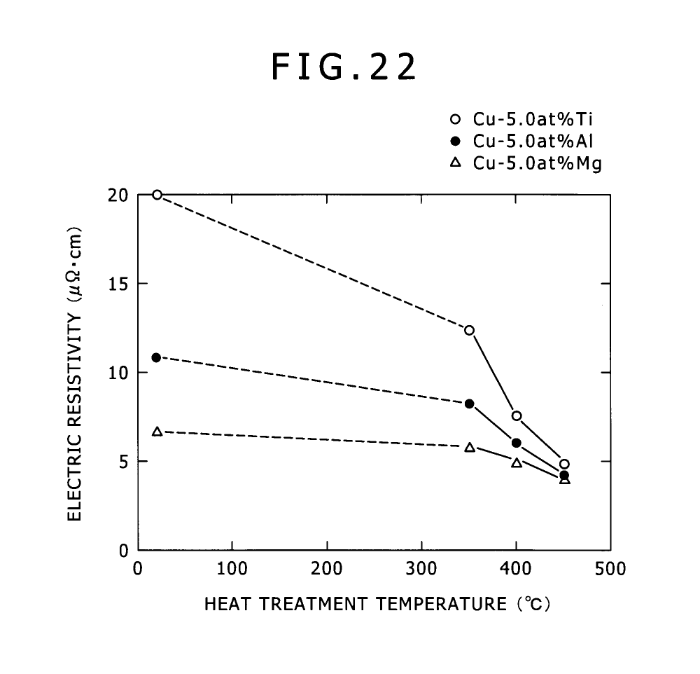

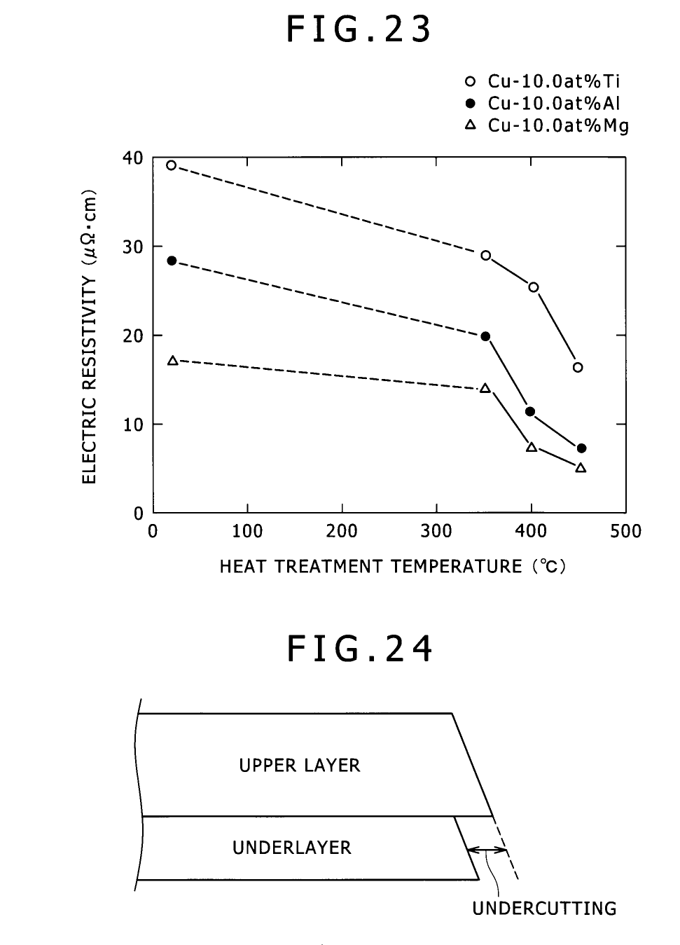

FIG. 21 is a graph showing how the electric resistivity varies depending on the heat treatment temperature in Cu multilayer films containing 2.0 atomic percent of X (Ti, Al, or Mg); FIG. 22 is a graph showing how the electric resistivity varies depending on the heat treatment temperature in Cu multilayer films containing 5.0 atomic percent of X (Ti, Al, or Mg); and FIG. 23 is a graph showing how the electric resistivity varies depending on the heat treatment temperature in Cu multilayer films containing 10.0 atomic percent of X (Ti, Al, or Mg).

FIGS. 21 to 23 demonstrate that the Cu multilayer films in an as-deposited state have an increasing electric resistivity proportionally with an increasing content of the alloy element; but that the heat treatment allows the Cu multilayer films to have a lower electric resistivity, and the Cu multilayer films subjected to a heat treatment at a temperature of 350° C. or higher have a dramatically lower electric resistivity than that of the corresponding Cu multilayer films in an as-deposited state.

Some Cu-based alloy films containing the alloy element in a high content and subjected to a heat treatment at a high temperature may show a high electric resistivity and may be difficult to be used as a single-layer interconnection. In these cases, the resulting interconnection can have a low effective electric resistivity to a level practically applicable without problems, by configuring the interconnection as a Cu multilayer film including a pure Cu film as the upper layer, and controlling the thickness of the underlayer.

### Example 8

Etching tests were performed in the following method to evaluate the wet etching properties of Cu multilayer films.

Cu multilayer films were deposited to give etching evaluation specimens (specimens in an as-depo state) by the procedure of Example 4, except for depositing Cu multilayer films given in Table 2 as the Cu multilayer film.

TABLE 2

| | Structure of Cu multilayer film | |
|---|---|---|
| No. | Upper layer (thickness) | Underlayer (thickness) |
| 1 | pure Cu (300 nm) | |
| 2 | pure Cu (250 nm) | Cu-10 atomic percent Al alloy (50 nm) |
| 3 | pure Cu (250 nm) | Cu-10 atomic percent Mg alloy (50 nm) |
| 4 | pure Cu (250 nm) | Cu-10 atomic percent Ti alloy (50 nm) |
| 5 | pure Cu (280 nm) | Cu-10 atomic percent Al alloy (20 nm) |
| 6 | pure Cu (200 nm) | Cu-10 atomic percent Al alloy (100 nm) |
| 7 | pure Cu (100 nm) | Cu-10 atomic percent Al alloy (200 nm) |

To form a stripe pattern with a line-and-space width of 10 μm, the specimens were subjected to photolithography and to etching with a 75:5:20 mixed acid etchant of phosphoric acid, nitric acid, and water. Multilayer thin film specimens such as the Cu multilayer films according to the present invention have etching rates different between the underlayer and the upper layer and, if the underlayer shows an etching rate higher than that of the upper layer, can suffer from undercut at the bottom of the interconnection (in the underlayer). Accordingly, the etched specimens were observed in the cross section of the interconnection film with a scanning electron microscope (SEM), the undercutting (undercut depth) as illustrated in FIG. 24 was measured, and the wet etching properties were evaluated.

The results demonstrate that all the specimens including the Cu multilayer films according to the present invention show an undercutting of 0.5 μm or less, have no problem in wet etching properties, and leave no residue in the etched portion.

While the present invention has been particularly shown and described with reference to specific embodiments, it will be understood by those skilled in the art that the foregoing and other changes and modifications can be made therein without departing from the spirit and scope of the present invention.

The present application contains subject matter related to Japanese Patent Application No. 2008-208960 filed on Aug. 14, 2008, the entire contents of which are incorporated herein by reference.

### INDUSTRIAL APPLICABILITY

The present invention provides a display device having a Cu alloy film which has a low electric resistance and thereby allows the display device (such as a liquid crystal display) to have a larger screen-size and to operate at higher frequencies. The Cu alloy film according to the present invention excels both in adhesion to a transparent substrate (glass substrate) and in etching properties, and, when adopted to a display device (such as a liquid crystal display), especially to gate electrodes and scanning lines of TFTs in the display device, can be deposited on a transparent substrate (glass substrate) without the formation of the Mo-containing underlayer. Thus, the Cu alloy film can gives a display device having high performance at lower production cost while avoiding the need of the Mo-containing underlayer.

### REFERENCE SIGNS LIST

1 TFT array substrate
1a glass substrate
2 counter substrate (counter electrode)
3 liquid crystal layer
4 thin film transistor (TFT)
5 pixel electrode (transparent conductive film)
6 interconnection
7 common electrode
8 color filter
9 light shielding film
10a, 10b polarizer
11 alignment layer
12 TAB tape
13 drive circuit
14 control circuit
15 spacer
16 sealant
17 protective film
18 diffuser panel
19 prism sheet
20 light guide panel
21 reflector plate
22 backlight
23 holding frame
24 printed circuit board
25 scanning line (gate interconnection)
26 gate electrode
27 gate insulating film
28 source electrode
29 drain electrode
30 passivation film (protective film, silicon nitride film)
31 photoresist layer
32 contact hole
34 signal line (source-drain interconnection)
100 liquid crystal display

1. A Cu alloy film comprising:
Cu; and
one or more elements selected from the group consisting of Ti, Al, and Mg in a total content of 0.1 to 10.0 atomic percent
wherein the Cu alloy film functions as an interconnection and the Cu alloy film is arranged on and in direct contact with a glass substrate.

2. A Cu alloy film comprising:
Cu; and
one or more elements selected from the group consisting of Ti, Al, and Mg in a total content of 0.1 to 5.0 atomic percent,
wherein the Cu alloy film functions as an interconnection and the Cu alloy film is arranged on and in direct contact with a glass substrate.

3. A Cu alloy film comprising:
Cu; and
one or more elements selected from the group consisting of Ti, Al, and Mg in a total content of 0.2 to 10.0 atomic percent,
wherein the Cu alloy film functions as an interconnection and the Cu alloy film is arranged on and in direct contact with a glass substrate.

4. The Cu alloy film according to claim 3, wherein the Cu alloy film has a multilayer structure comprising
an underlayer containing oxygen and
an upper layer being substantially free from oxygen, and
wherein the underlayer is in contact with the substrate.

5. A Cu alloy film comprising
a multilayer structure;
wherein the multilayer structure comprises
an underlayer comprising oxygen and a Cu alloy comprising one or more elements selected from the group consisting of Ti, Al, and Mg in a total content of 0.2 to 10.0 atomic percent, and
an upper layer being substantially free from oxygen and containing pure Cu or a Cu alloy, the Cu alloy comprising Cu as a main component and having an electric resistivity lower than that of the underlayer,
wherein the underlayer is in contact with a glass substrate, and
wherein the Cu alloy film functions as an interconnection and the Cu alloy film is arranged on and in direct contact with the glass substrate.

6. The Cu alloy film according to claim 4, wherein the underlayer is formed through sputtering with a sputtering gas having an oxygen content of 1 percent by volume or more and less than 20 percent by volume.

7. The Cu alloy film according to claim 4 wherein the underlayer has a thickness of 10 nm or more and 200 nm or less.

8. A display device comprising at least one thin film transistor, and each transistor comprising the Cu alloy film as claimed in claim 1.

9. The display device according to claim 8, wherein
the thin film transistor has a bottom-gate structure,
the glass substrate comprises at least one gate electrode and at least one scanning line of the thin film transistor, and
the gate electrode and the scanning line comprise the Cu alloy film.

10. A flat panel display comprising the display device according to claim 8.

11. A Cu alloy sputtering target comprising a Cu alloy comprising one or more elements selected from the group consisting of Ti, Al, and Mg in a total content of 0.1 to 10.0 atomic percent.
